(19) United States
(12) Patent Application Publication
(10) Pub. No.: US 2013/0160712 A1
(43) Pub. Date: Jun. 27, 2013

(54) EVAPORATION CELL AND VACUUM DEPOSITION SYSTEM THE SAME

(71) Applicant: Manabu Niboshi, Osaka (JP)

(72) Inventor: Manabu Niboshi, Osaka (JP)

(73) Assignee: SHARP KABUSHIKI KAISHA, Osaka (JP)

(21) Appl. No.: 13/820,069

(22) PCT Filed: Aug. 25, 2011
(86) PCT No.: PCT/JP2011/004723

§ 371 Date: Feb. 28, 2013

(30) Foreign Application Priority Data
Sep. 1, 2010 (JP) 2010-195676

(51) Int. Cl. C23C 16/448

(52) U.S. Cl. CPC C23C 16/4485
USPC 118/726

(57) ABSTRACT

An evaporation cell includes a crucible (21) containing a deposition material (M), an electric heater (22) which heats the crucible (21) and thereby preliminarily heats the deposition material (M) contained in the crucible (21) in an indirect manner to a temperature range in which vaporization of the deposition material (M) does not occur; and a lamp heater (24) which directly heats the deposition material (M) contained in the crucible (21) and thereby primarily heats the preliminarily heated deposition material (M) to a temperature equal to or higher than its vaporization temperature.

### TECHNICAL FIELD

The present disclosure relates to evaporation cells and vacuum deposition systems including the same, and particularly to measures against deterioration of organic materials which is caused when the organic materials are subjected to vapor deposition.

### BACKGROUND ART

Vapor deposition performed in a vacuum deposition system is widely used to, for example, form an organic electro luminescence (EL) layer in processes of producing organic EL devices. Resistance heating type deposition systems are vacuum deposition systems which are generally used, and each include a vacuum chamber having an evaporation cell provided therein and a substrate holder for holding a target substrate at a position above and opposite to the evaporation cell. The evaporation cell includes a ceramic crucible for containing, e.g., a conductive deposition material, and a heater for heating the crucible. The evaporation cell indirectly heats the deposition material contained in the crucible by heating the crucible with the heater so that the deposition material vaporizes, and thereby emits vapor of the deposition material to cause the vapor to flow. The deposition system then causes the deposition material emitted from the evaporation cell to be attached on the target substrate which is positioned opposite to the evaporation cell, resulting in that a film is formed on a surface of the target substrate.

An organic material used as a deposition material in the above resistance heating type deposition systems (hereinafter referred to as the organic deposition material) sometimes has a large thermal capacity caused by, e.g., a heat-transfer medium added to the organic deposition material in order to supplement thermal conductivity. In such a case, the organic deposition material has low thermal responsiveness, and accordingly, it is difficult to increase the temperature of the organic deposition material by indirectly heating the organic deposition material through the crucible with the heater, and to control start of emission of the organic deposition material. Accordingly, a method in which a plurality of target substrates are successively subjected to vapor deposition while keeping an organic deposition material constantly vaporizing is adopted. This method, however, inefficiently utilizes the material because the vapor is continuously emitted to flow even during a replacement of the target substrates. In view of this disadvantage, there have conventionally been proposed deposition systems to suitably control start of emission of a deposition material. For example, Patent Document 1 describes a configuration in which a needle valve is provided in a passage communicating with the inside of a crucible and allowing vapor of an organic deposition material to pass therethrough, the organic deposition material contained in the crucible is constantly heated and maintained at high temperatures where vaporization of the organic deposition material occurs, and emission of the organic deposition material is started by switching the needle valve from a closed position to an open position.

### Citation List

### Patent Document

PATENT DOCUMENT 1: Japanese Patent publication No. 2003-95787

### SUMMARY OF THE INVENTION

### Technical Problem

In the deposition system described in Patent Document 1, however, since it is necessary to maintain the organic deposition material contained in the crucible at high temperatures equal to or higher than its vaporization temperature, the organic deposition material may easily suffer heat damage. The organic deposition material may adversely deteriorate when having been maintained at high temperatures for a long period of time. This deterioration is particularly likely to occur when a deposition rate is intended to be increased under a high vapor pressure.

It is therefore an object of the present disclosure to control start of vaporization of an organic deposition material in a suitable manner while reducing deterioration of the organic deposition material when the organic deposition material is subjected to vapor deposition.

### Solution to the Problem

In order to achieve the object, in the present disclosure, a desired vapor pressure is obtained at a desired timing by performing pulse heating with which an organic deposition material is heated to its vaporization temperature only when vapor deposition is carried out.

Specifically, the present disclosure relates to an evaporation cell for evaporating an organic deposition material and a vacuum deposition system including the evaporation cell, and provides solutions as will be describes below.

Thus, a first aspect of the present disclosure is the evaporation cell comprising: a crucible containing an organic deposition material; a preliminary heating means which heats the crucible and thereby preliminarily heats the organic deposition material contained in the crucible in an indirect manner to a temperature range in which vaporization of the organic deposition material does not occur; and a primary heating means which directly heats the organic deposition material contained in the crucible and thereby primarily heats the preliminarily heated deposition material to a temperature equal to or higher than a vaporization temperature of the deposition material.

According to the first aspect of the present disclosure, the preliminary heating means preliminarily heats the organic deposition material in an indirect manner to the temperature range in which vaporization of the organic deposition material does not occur, and then the primary heating means primarily heats the preliminarily heated organic deposition material in a direct manner to a temperature equal to or higher than the vaporization temperature. Accordingly, the organic deposition material is rapidly heated to a temperature equal to or higher than the vaporization temperature, as compared to a case where the organic deposition material is primarily heated through the crucible in an indirect manner, and it is possible to cause the organic deposition material to start vaporizing quickly in synchronization with the primary heating. Thus, the primary heating means makes it possible to control start of vaporization of the organic deposition material in a suitable manner, and a desired vapor pressure can be obtained at a desired timing by heating the organic deposition material to its vaporization temperature only when vapor deposition is carried out. As a result, it is unnecessary to maintain the organic deposition material at high temperatures where vaporization of the organic deposition material occurs by constantly heating the organic deposition material, and therefore, heat damage to, and deterioration of, the organic deposition material can be reduced.

A second aspect of the present disclosure is the evaporation cell of the first aspect in which the preliminary heating means preliminarily heats the organic deposition material to a temperature lower than the vaporization temperature by 5-10° C., inclusive.

If the organic deposition material to be primarily heated by the primary heating means was at a temperature lower than the vaporization temperature by less than 5° C., the heat damage to the organic deposition material might be insufficiently reduced because the organic deposition material would be maintained at relatively high temperatures approximate to the vaporization temperature. On the other hand, if the organic deposition material was at a temperature lower than the vaporization temperature by more than 10° C., it would take a relatively long time for the primary heating means to primarily heat the organic deposition material to a temperature equal to or higher than the vaporization temperature. In contrast, according to the second aspect of the present disclosure, it is possible to sufficiently reduce the heat damage to, and deterioration of, the organic deposition material while heating the organic deposition material to a temperature equal to or higher than the vaporization temperature within a relatively short time by means of the primary heating means.

A third aspect of the present disclosure is the evaporation cell of the second aspect, in which the primary heating means heats the organic deposition material at a temperature rise rate of 1° C. or more per second.

According to the third aspect of the present disclosure, since the organic deposition material, which has been preliminarily heated to a temperature lower than the vaporization temperature by 5-10° C., inclusive, is rapidly heated at a temperature rise rate of over 1° C. or more per second, it is possible to cause the organic deposition material to reach the vaporization temperature within 10 seconds from start of heating by the primary heating means, and to start vaporizing quickly.

A fourth aspect of the present disclosure is the evaporation cell of any one of the first through third aspects, in which the preliminary heating means is an electrical resistance element which generates heat by passage of an electric current, and the evaporation cell further includes a cooling means which cools the electrical resistance element and thereby reduces heat generated by the electrical resistance element.

According to the fourth aspect of the present disclosure, when a temperature of the crucible exceeds a predetermined range, that is, when the organic deposition material contained in the crucible is heated to a temperature exceeding a predetermined temperature, the cooling means cools the electrical resistance element serving as the preliminary heating means and reduces the heat generated by the electrical resistance element. Consequently, it is possible to adjust the temperature of the organic deposition material in a suitable manner within a predetermined temperature range.

A fifth aspect of the present disclosure is the evaporation cell of any one of the first through fourth aspects, in which the primary heating means is a lamp heater.

In the fifth aspect of the present disclosure, a lamp heater is adopted as the primary heating means. The lamp heater is sufficiently controllable and capable of performing rapid heating with high efficiency. Even with direct heating, the lamp heater causes less damage to the organic deposition material, as compared to the other heating means radiating high-density energy such as a laser beam. Therefore, the lamp heater suitably serves as the primary heating means. Furthermore, since the primary heating by the lamp heater heats, in particular, a surface portion of the organic deposition material and allows the surface portion to vaporize, the vaporization of the organic deposition material is stopped quickly in synchronization with stopping the primary heating. Consequently, both of start and stop of the vaporization of the organic deposition material can be suitably controlled by activating or deactivating the primary heating means, and the evaporation cell of the present disclosure can be suitably implemented.

A sixth aspect of the present disclosure is a vacuum deposition system including the evaporation cell of any one of the first through fifth aspects, a substrate holder configured to hold a target substrate above the evaporation cell, and a vacuum chamber within which the evaporation cell and the substrate holder are provided.

According to the sixth aspect of the present disclosure, the evaporation cell of any one of the first through fifth aspects has excellent characteristics of being capable of controlling start of vaporization of the organic deposition material in a suitable manner and reducing deterioration of the organic deposition material. Accordingly, it is possible to improve utilization efficiency of the organic deposition material and to form an organic film having favorable characteristics on a surface of the target substrate.

### Advantages of the Invention

According to the present disclosure, the preliminary heating means preliminarily heats the organic deposition material, and the preliminarily heated material is then primarily heated by the primary heating means. Accordingly, when the organic deposition material is subjected to vapor deposition, it is possible to control start of vaporization of the organic deposition material in a suitable manner and to reduce deterioration of the organic deposition material. As a result, utilization efficiency of the organic deposition material can be improved and an organic film having favorable characteristics can be obtained.

### BRIEF DESCRIPTION OF THE DRAWINGS

FIG. 1 schematically illustrates a configuration of a vacuum deposition system according to an embodiment.

FIG. 2 is a cross-sectional view schematically illustrating a configuration of an evaporation cell according to the embodiment.

FIG. 3 is a flowchart showing a method for depositing a material on a target substrate using the vacuum deposition system according to the embodiment.

FIG. 4(a) is a graph showing film forming operation by a conventional vacuum deposition system. FIG. 4(b) is a graph showing film forming operation by the vacuum deposition system according to the embodiment.

FIGS. 5(a), 5(b) and 5(c) are graphs respectively showing analytical data of molecular orientation obtained by X-ray diffraction in connection with an organic deposition material before performing vapor deposition, the organic deposition material after performing vapor deposition in the vacuum deposition system of the embodiment, and the organic deposition material after performing vapor deposition in a conventional vacuum deposition system.

### DESCRIPTION OF EMBODIMENTS

An embodiment of the present disclosure will be described below with reference to the drawings. Note that the present disclosure is not limited to the embodiment described below.

### Embodiment of Disclosure

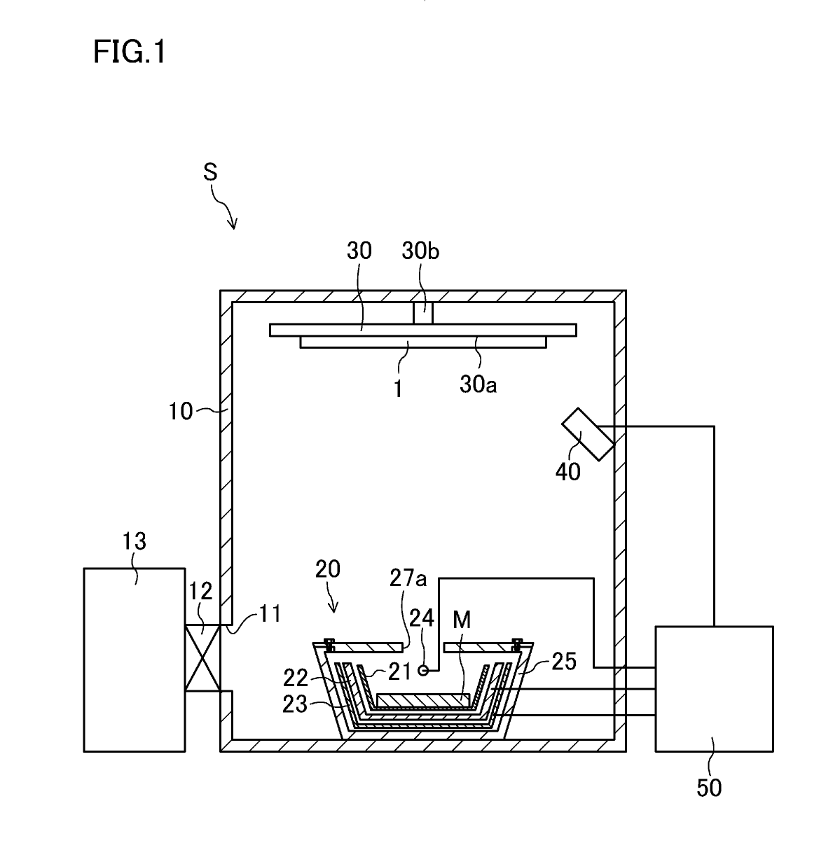

FIG. 1 schematically illustrates a configuration of a vacuum deposition system S according to this embodiment.

The vacuum deposition system S is used to form an organic film by depositing an organic material on a surface of a target substrate 1 such as a glass substrate. The vacuum deposition system S includes a vacuum chamber 10, an evaporation cell 20 provided near the bottom of the vacuum chamber 10, a substrate holder 30 provided near the ceiling of the vacuum chamber 10 so as to hold the target substrate 1 at a position above and opposite to the evaporation cell 20, a deposition rate sensor 40 provided at a position located at a side of the substrate holder 30 and nearer a substrate holding face 30a of the substrate holder 30, and a controller 50.

The vacuum chamber 10 includes a vent 11 provided in a side wall, and the vent 11 is connected to a vacuum pump 13 through a gate valve 12. Activating the vacuum pump 13 can expel air from the chamber and decompress the chamber to create high vacuum conditions. For example, an oil-sealed rotary pump, a dry vacuum pump, a diffusion pump, or a cryopump can be used as the vacuum pump 13, and another pump such as a mechanical booster pump may be used in combination with the vacuum pump 13, if necessary.

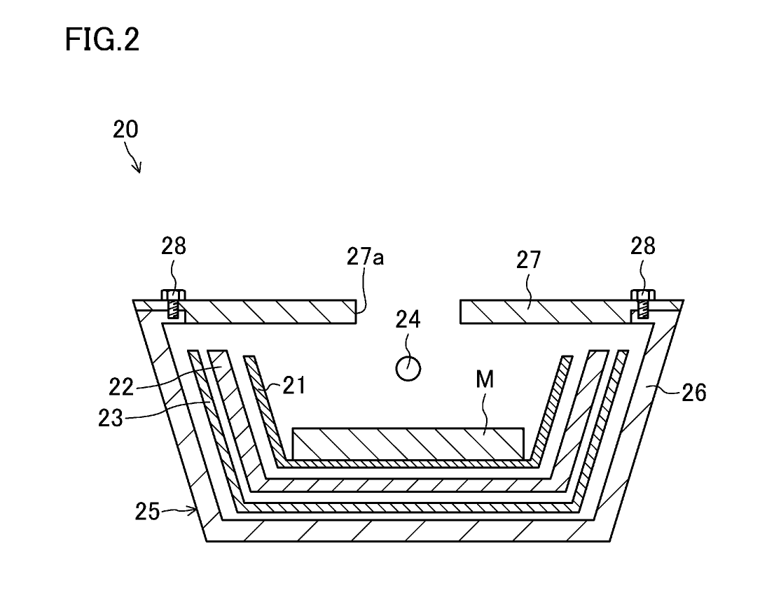

FIG. 2 schematically illustrates a configuration of the evaporation cell 20. The evaporation cell 20 includes a crucible 21 for containing an organic deposition material M, an electric heater 22 of a resistance heating type provided around the crucible 21 and serving as a preliminary heating means, a cooling heat exchanger 23 surrounding the electric heater 22 and serving as a cooling means, a lamp heater 24 provided in the crucible 21 and serving as a primary heating means, and a cover container 25 accommodating the foregoing components. The evaporation cell 20 is configured such that the electric heater 22 indirectly heats the organic deposition material M contained in the crucible 21 and the lamp heater 24 directly heats the deposition material M.

The crucible 21 has an opening at the upper side and is formed in, e.g., a cylindrical shape which has a bottom and increases in diameter toward the opening. The crucible 21 is made of, e.g., heat-resistance ceramic such as pyrolytic boron nitride (PBN), silicon carbide (SiC), aluminum nitride (AlN), and alumina (Al₂O₃), or a refractory metal material such as stainless steel (SUS), titanium (Ti), and tungsten (W).

The electric heater 22 is made of a heating wire which is an electrical resistance element generating heat by passage of an electric current, and connected to a power supply circuit (not shown) which supplies a direct current to the heating wire. The heating wire, which is helically wound around the outer periphery of the crucible 21, heats the crucible 21 by transferring heat of itself, and thereby preliminarily heats the organic deposition material M in an indirect manner to a temperature range in which vaporization of the organic deposition material M does not occur.

The cooling heat exchanger 23 includes, e.g., a cooling tube provided around the electric heater 22 or a cooling cover having a fluid passage formed therein, and is configured to circulate a coolant such as cooling water or liquid nitrogen inside the cooling heat exchanger. When the temperature of the crucible 21 exceeds a predetermined range, that is, when the organic deposition material M contained in the crucible 21 is heated to a temperature exceeding a predetermined temperature, the cooling heat exchanger 23 cools the heating wire by means of circulation of the coolant to reduce the heat generated by the electric heater 22, and thereby adjusts the temperature of the organic deposition material M within a predetermined temperature range.

The lamp heater 24 is an infrared lamp heater or a halogen lamp heater in, e.g., a linear tubular shape. The lamp heater 24 primarily and directly heats the organic deposition material M, which is contained in the crucible 21 and has been preliminarily heated, to a temperature equal to or higher than its vaporization temperature. The lamp heater 24 is sufficiently controllable and capable of performing rapid heating with high efficiency. Even with direct heating, the lamp heater 24 causes less damage to the organic deposition material M, as compared to the other heating means radiating high-density energy such as a laser beam. Therefore, the lamp heater 24 suitably serves as the primary heating means. Although FIGS. 1 and 2 illustrate the configuration including the lamp heater 24 as the only lamp heater, a plurality of lamp heaters may be provided. The lamp heater 24 is not limited to the linear tubular shape as exemplified above, and lamp heaters in various shapes such as a mesh type one can be adopted as long as the lamp heaters do not block the vapor flow of the organic deposition material M from the crucible 21.

The cover container 25 includes an accommodation part 26 which is larger than the crucible 21 in diameter and formed in a cylindrical shape with a bottom similarly to the crucible 21, and a lid member 27 covering an opening of the accommodation part 26. The accommodation part 26 and the lid member 27 are made of ceramic and configured to reduce the amount of heat radiating from the electric heater 22 and the crucible 21 to the outside. For example, the rim of the lid member 27 is fixed to the accommodation part 26 with bolts 28. The lid member 27 has a circular opening 27a formed in the central portion and narrowing the opening through which the vapor of the organic deposition material M vaporizing in the crucible 21 is emitted.

In the evaporation cell 20 with the narrowed opening as described above, the diameter of the opening 27a is smaller than that of the inner space of the accommodation part 26. The vapor of the organic deposition material M produced in the inner space having a relatively large cross-section area increases in flow velocity and decreases in pressure when passing through the opening 27a having a relatively small cross-section area. Consequently, the vapor is emitted at high speed from the opening 27a and effectively dispersed. As illustrated in FIG. 1, the substrate holder 30 holds the target substrate 1 on the substrate holding face 30a facing the evaporation cell 20 by means of, e.g., electrostatic adsorption. The substrate holder 30 may include a holder rotation mechanism which rotates the substrate holder 30 via a rotation axis 30b provided parallel to the direction of the normal of the substrate holding face 30a so as to form a film on a surface of the target substrate 1 held by the substrate holder 30 while rotating the target substrate 1 using the holder rotation mechanism.

The deposition rate sensor 40 includes, e.g., a quartz oscillator and is configured to measure a film thickness formed per a unit time (i.e., a deposition rate) on the basis of change in frequency caused by the organic deposition material M attached on the quartz oscillator. The controller 50 is connected to the electric heater 22, the cooling heat exchanger 23, and a thermocouple (not shown) provided near the crucible 21. The controller 50 monitors the temperature of the crucible 21 using the thermocouple, and controls the temperature of the crucible 21 by operating the electric heater 22 and the cooling heat exchanger 23 by means of, e.g., proportional integral difference control (PID control) so that the crucible 21 is at a desired temperature. In this manner, the organic deposition material M is preliminarily heated to be within the temperature range in which vaporization of the organic deposition material M does not occur, specifically to a temperature lower than the vaporization temperature by 5-10° C., inclusive.

If the organic deposition material M to be primarily heated by the lamp heater 24 was at a temperature lower than the vaporization temperature by less than 5° C., the heat damage to the organic deposition material M might be insufficiently reduced because the organic deposition material M would be maintained at relatively high temperatures approximate to the vaporization temperature. On the other hand, if the organic deposition material M was at a temperature lower than the vaporization temperature by more than 10° C., it would take a relatively long time for the lamp heater 24 to primarily heat the organic deposition material M to a temperature equal to or higher than the vaporization temperature. In contrast, since the organic deposition material M which has been preliminarily heated in this embodiment is at a temperature lower than the vaporization temperature by 5-10° C., inclusive, it is possible to sufficiently reduce the heat damage to, and deterioration of, the organic deposition material M while heating the organic deposition material M to a temperature equal to or higher than the vaporization temperature within a relatively short time by means of the lamp heater 24.

Further, the controller 50 is also connected to the lamp heater 24 and the deposition rate sensor 40. Accordingly, the controller 50 causes the lamp heater 24 to heat the organic deposition material M rapidly at a temperature rise rate of 1° C. or more per second so that the organic deposition material M starts vaporizing, and monitors the rate of deposition on the target substrate 1 using the deposition rate sensor 40. The controller 50 adjusts the power supplied to the lamp heater 24 to achieve a desired deposition rate, and controls heating conditions of the organic deposition material M heated by the lamp heater 24. In the vacuum deposition system S having the above configuration, the electric heater 22 and the cooling heat exchanger 23 preliminarily heat the organic deposition material M contained in the crucible 21 and maintain the organic deposition material M in temperature conditions resulting from the preliminary heating, and the lamp heater 24 primarily heats the organic deposition material M in a direct manner to the vaporization temperature only when vapor deposition is carried out, thereby causing the organic deposition material M to start vaporizing to be deposited on a surface of the target substrate 1. The vacuum deposition system S stops vaporization of the organic deposition material M by stopping the primary heating performed by the lamp heater 24, thereby finishing vapor deposition of the organic material on the substrate. With this configuration, it is possible to control start and stop of vaporization of the organic deposition material M in a suitable manner and to reduce the deterioration of the organic deposition material M.

In other words, since the organic deposition material M, which has been preliminarily heated to a temperature lower than the vaporization temperature by 5-10° C., inclusive, is primarily heated by the lamp heater 24 at a temperature rise rate of 1° C. or more per second, the organic deposition material M is rapidly heated (within 10 seconds) to a temperature equal to or higher than the vaporization temperature, as compared to a case where the organic deposition material M is primarily heated through the crucible 21 in an indirect manner. Accordingly, it is possible to cause the organic deposition material M to start vaporizing quickly in synchronization with the primary heating. Furthermore, the primary heating by the lamp heater 24 heats, in particular, a surface portion of the organic deposition material M and allows the surface portion to vaporize, it is possible to stop the vaporization of the organic deposition material M quickly in synchronization with stopping the primary heating. In this manner, start and stop of the vaporization of the organic deposition material M can be suitably controlled by activating or deactivating the lamp heater 24, and accordingly, it is unnecessary to maintain the organic deposition material M at high temperatures where vaporization of the organic deposition material M occurs, resulting in that the heat damage to, and deterioration of, the organic deposition material M can be reduced.

Deposition Method

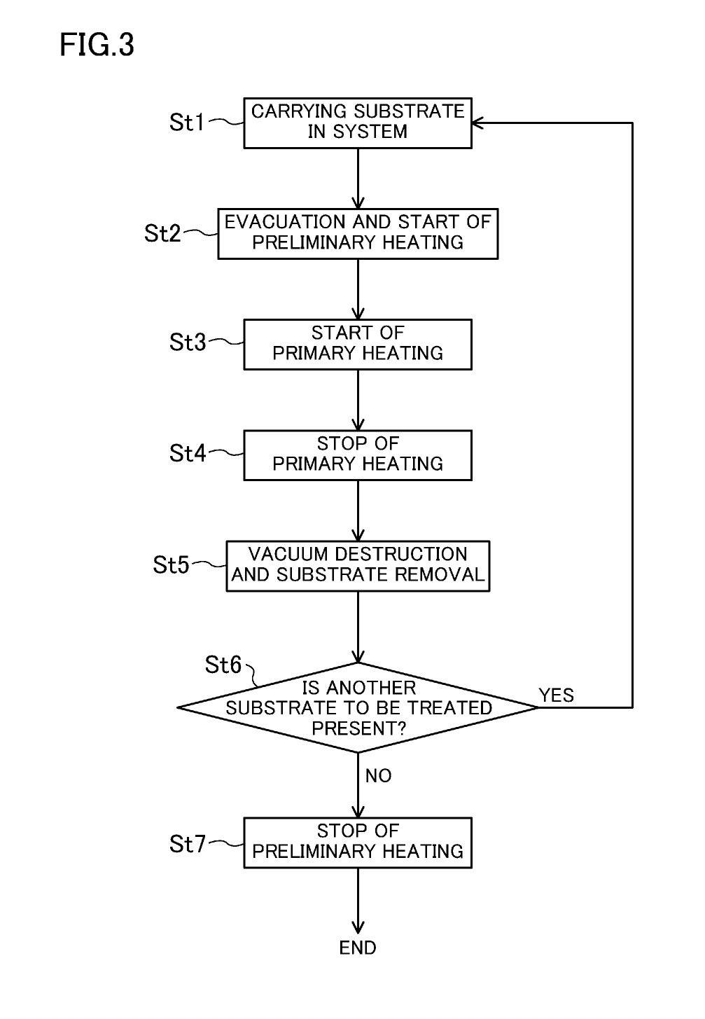

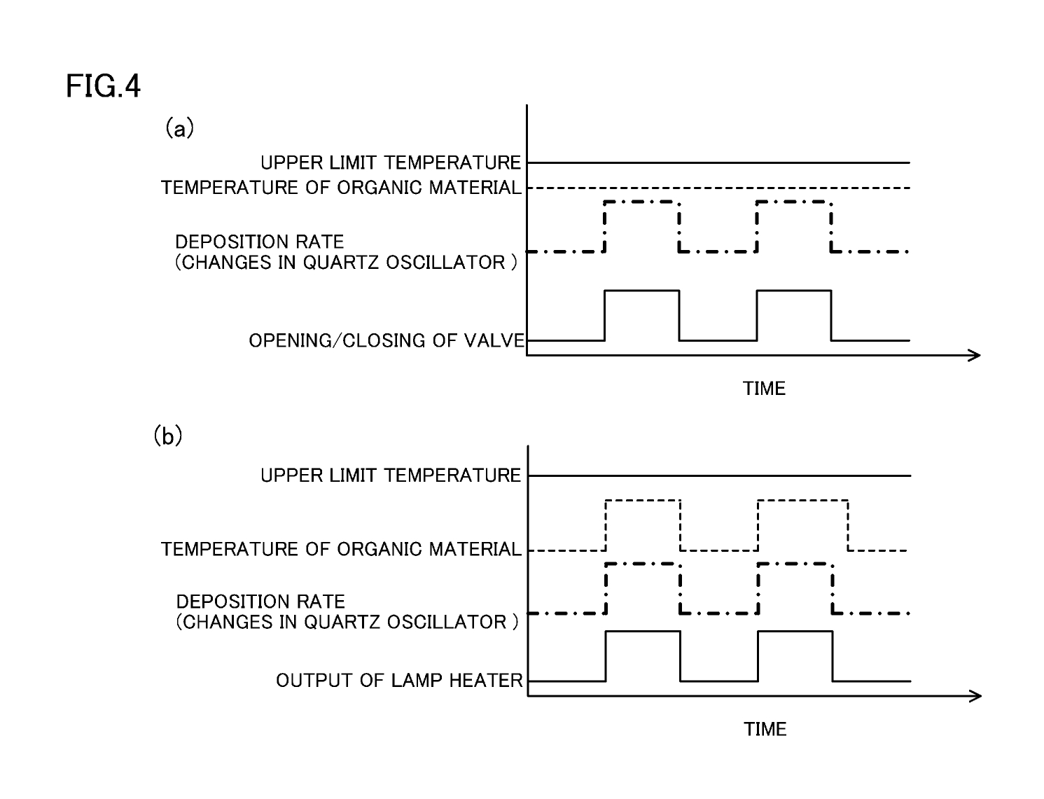

Next, in order to describe a method for forming an organic film on surfaces of a plurality of target substrates 1 by using the vacuum deposition system S, an example will be given and described with reference to FIGS. 3 and 4. FIG. 3 is a flowchart showing a method for depositing a material on the target substrates 1. FIG. 4(a) is a graph showing film forming operation by a vacuum deposition system as described in Patent Document 1 which starts or stops emission of the organic deposition material M by opening/closing a needle valve. FIG. 4(b) is a graph showing film forming operation by the vacuum deposition system S according to this embodiment. Note that the upper limit temperature shown in FIG. 4 refers to a temperature at which the organic deposition material M suffers decomposition or heat damage.

First, a first one of the target substrates 1 is carried in the vacuum chamber 10 and held by the substrate holder 30 (St 1). Next, the vacuum pump 13 is activated to evacuate the vacuum chamber 10, thereby producing a high vacuum of 1.0×10 ⁻⁴ Pa or less, for example. At the same time, the electric heater 22 and the cooling heat exchanger 23 are activated to preliminarily and indirectly heat the organic deposition material M which has previously been put in the crucible 21 to a temperature lower than the vaporization temperature by 5-10° C., inclusive, and to maintain the organic deposition material M within this temperature range (St 2). Note that, when having been subjected to press forming prior to setting in the crucible 21, the organic deposition material M increases in thermal conductivity, and accordingly, its thermal responsiveness can be improved.

Further, the lamp heater 24 is activated to primarily heat the organic deposition material M to a temperature equal to or higher than its vaporization temperature at a temperature rise rate of 1° C. or more per second in a direct manner. Then, the organic deposition material M is caused to start vaporizing quickly, and the organic deposition material M emitted from the evaporation cell 20 is caused to be attached on the target substrate 1 which is positioned opposite to the evaporation cell 20, thereby depositing the organic deposition material M on a surface of the target substrate 1 (St 3). Upon obtainment of an organic film having a predetermined thickness on the surface of the target substrate 1, the lamp heater 24 is deactivated to quickly stop the vaporization of the organic deposition material M, thereby completing formation of the organic film on the first one of the target substrates 1 (St 4).

The vacuum in the vacuum chamber 10 is then destroyed, and the first treated target substrate on which the organic film has been formed is removed from the vacuum chamber 10 (St 5). In this step, the organic deposition material M is being continuously subjected to the preliminary heating to be maintained within the temperature range in which vaporization of the organic deposition material M does not occur (at a temperature lower than the vaporization temperature by 5-10° C., inclusive).

Thereafter, it is determined whether or not another target substrate 1 (another substrate which has not been treated) is present (St 6). If another target substrate 1 is present, the target substrate 1 to be treated is carried into the vacuum chamber 10 and held by the substrate holder 30 (St 1), and St 2-St 5 described above are performed in a similar manner. When the second and subsequent target substrates 1 are to be subjected to film formation, since the organic deposition material M is already in a state resulting from the preliminarily heating, only the evacuation of the vacuum chamber 10 is performed in St 2 described above. If no other target substrate 1 is present, the electric heater 22 and the cooling heat exchanger 23 are deactivated to stop the preliminary heating of the organic deposition material M (St 7), and the film formation of the target substrate 1 is finished.

In the above-described manner, a plurality of target substrates 1 can be subjected to the film formation treatment. As described above, in the vacuum deposition system S of this embodiment performing pulse heating with which the organic deposition material M is heated to its vaporization temperature only when vapor deposition is carried out, a desired vapor pressure is obtained at a desired timing. Therefore, as shown in FIG. 4(b), the organic deposition material M reaches a high temperature equal to or higher than the vaporization temperature only when the film formation is carried out in the vacuum deposition system S of this embodiment. As compared to film formation performed in a conventional vacuum deposition system in which, as shown in FIG. 4(a), the organic deposition material M is constantly maintained at high temperatures, the vacuum deposition system S of this embodiment can reduce the heat damage to the organic deposition material M.

Evaluation Experiment

Next, an evaluation experiment which was specifically conducted to evaluate deterioration degrees of the organic deposition material M in the vacuum deposition system S will be described below.

In this evaluation experiment, an analysis by X-ray diffraction (XRD) was conducted on molecular orientation (a stacking state) of each of the organic deposition material M before performing vapor deposition, i.e., before heating, the material M after performing vapor deposition in the vacuum deposition system S of this embodiment, and the material M after performing vapor deposition in a conventional vacuum deposition system.

A comparison of the data obtained by the analyses was made to evaluate the deterioration degrees of the organic deposition material M. As the organic deposition material M, NPD (product of e-Ray Optoelectronics Technology Co., Ltd.; C₄₄H₃₂N₂) was used.

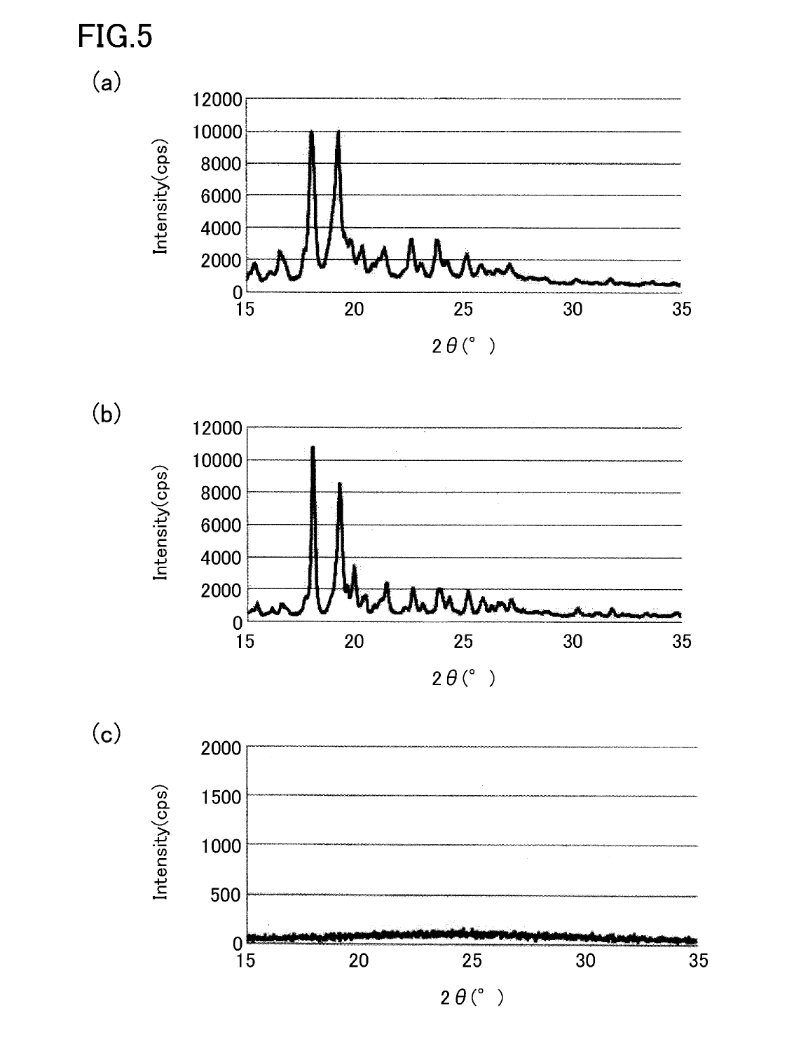

The conventional vacuum deposition system has the same configuration as that of the vacuum deposition system S of this embodiment except that the lamp heater 24 was not provided. This vacuum deposition system was configured to heat the organic deposition material M to a temperature equal to or higher than the vaporization temperature with the electric heater 22. The organic deposition material M after performing vapor deposition was obtained by heating the organic deposition material M in each of the vacuum deposition system S of this embodiment and the conventional vacuum deposition system until the deposition rate reached 10 nm per second. In the conventional vacuum deposition system, the organic deposition material M needed to be heated up to 250° C. so that the deposition rate reached 10 nm per second. On the other hand, in the vacuum deposition system of this embodiment, it was enough to heat the organic deposition material M to 200° C. FIG. 5 shows the analytical results obtained by the X-ray diffraction. FIGS. 5(a), 5(b) and 5(c) are graphs respectively showing the analytical data obtained in connection with the organic deposition material M before performing vapor deposition, the material M after performing vapor deposition in the vacuum deposition system S, and the material M after performing vapor deposition in the conventional vacuum deposition system. In FIG. 5, each vertical axis represents diffracted intensity of X-ray and each horizontal axis represents incident angles of X-ray.

As shown in FIG. 5(a), the organic deposition material M before performing vapor deposition exhibited two peaks of the substantially same diffracted intensity in the range where the incident angle is 20° or less. Regarding the organic deposition material M after performing vapor deposition in the conventional vacuum deposition, as shown in FIG. 5(c), both of the two peaks almost disappeared. This means that the organic deposition material M after performing vapor deposition in the conventional vacuum deposition system suffered considerable heat damage and severe deterioration. On the other hand, the organic deposition material M after performing vapor deposition in the vacuum deposition system S of this embodiment exhibited the data approximate to the data of the organic deposition material M before performing vapor deposition, although the peak at the smaller incident angle exceeded the other peak at the larger incident angle and a greater tendency to crystallize was demonstrated. These results teach that the organic deposition material M after performing vapor deposition in the vacuum deposition system S of this embodiment suffered small heat damage and slight deterioration.

Advantages of Embodiment

In this embodiment, start and stop of vaporization of the organic deposition material M can be suitably controlled by heating or not heating the organic deposition material M with the lamp heater 24, and therefore, a desired vapor pressure can be obtained at a desired timing. Thus, it is unnecessary to maintain the organic deposition material M at high temperatures where vaporization of the organic deposition material M occurs by constantly heating the organic deposition material M, and heat damage to, and deterioration of, the organic deposition material M can be reduced. As a result, it is possible to improve utilization efficiency of the organic deposition material and to form an organic film having favorable characteristics on the target substrate 1.

Although the above embodiment exemplifies the electric heater 22 of a resistance heating type as the preliminary heating means and the lamp heater 24 as the primary heating means, the present disclosure is not limited to this configuration. Other heating means such as a high-frequency dielectric heating type coil heater may be used as the preliminary heating means. Other heating means capable of rapidly heating the organic deposition material M, such as a laser heater emitting an infrared laser beam or an ultraviolet laser beam, or an electron beam heater, may be adopted as the primary heating means.

The above embodiment has been described as a preferred embodiment. The technical scope of the present disclosure, however, is not limited to the scope that the above embodiment describes. Those skilled in the art will understand that the above embodiment is described as an example, and combinations of the components and the process steps of the present disclosure may include further variations which are also included in the scope of the present disclosure.

### INDUSTRIAL APPLICABILITY

As described above, the present disclosure is useful for an evaporation cell and a vacuum deposition system including the evaporation cell. The present disclosure is particularly useful for an evaporation cell of which it is required to control start of vaporization of an organic deposition material and to reduce deterioration of the organic deposition material, and for a vacuum deposition system including the evaporation cell.

### DESCRIPTION OF REFERENCE CHARACTERS

S Vacuum Deposition System

M Organic Deposition Material

1 Target Substrate

10 Vacuum Chamber

20 Evaporation Cell

21 Crucible

22 Electric Heater (Preliminary Heating Means)

23 Cooling Heat Exchanger (Cooling Means)

24 Lamp Heater (Primary Heating Means)

30 Substrate Holder

1. An evaporation cell for evaporating an organic material, the evaporation cell comprising:
a crucible containing a deposition material;
a preliminary heating means which heats the crucible and thereby preliminarily heats the deposition material contained in the crucible in an indirect manner to a temperature range in which vaporization of the deposition material does not occur; and
a primary heating means which is provided in the crucible, and which directly heats the deposition material contained in the crucible and thereby primarily heats the preliminarily heated deposition material to a temperature equal to or higher than a vaporization temperature of the deposition material only when vapor deposition is performed.

2. The evaporation cell of claim 1, wherein the preliminary heating means preliminarily heats the deposition material to a temperature lower than the vaporization temperature by 5-10° C., inclusive.

3. The evaporation cell of claim 1, wherein
the primary heating means heats the deposition material at a temperature rise rate of 1° C. or more per second.

4. The evaporation cell of claim 1, wherein
the preliminary heating means is an electrical resistance element which generates heat by passage of an electric current, and
the evaporation cell further includes a cooling means which cools the electrical resistance element and thereby reduces heat generated by the electrical resistance element.

5. The evaporation cell of claim 1, wherein
the primary heating means is a lamp heater.

6. A vacuum deposition system comprising:
the evaporation cell of claim 1;
a substrate holder configured to hold a target substrate above the evaporation cell; and
a vacuum chamber within which the evaporation cell and the substrate holder are provided.

7. A method for forming an organic film on each of multiple target substrates by using the vacuum deposition system of claim 6, the method comprising:
a carrying step of carrying one of the multiple target substrates in the vacuum chamber and causing the target substrate to be held by the substrate holder;
an evacuation step of creating a vacuum by evacuating the vacuum chamber containing the target substrate;
a preliminary heating step of preliminarily and indirectly heating the deposition material contained in the crucible with the preliminary heating means to the temperature range in which vaporization of the deposition material does not occur;
a film formation step of forming the organic film by primarily heating the preliminarily heated deposition material to a temperature equal to or higher than the vaporization temperature to cause the deposition material to start vaporizing and thereby depositing the organic material on a surface of the target substrate, where the primary heating with the primary heating means is stopped upon obtainment of the organic film having a predetermined thickness; and
a removal step of removing the target substrate on which the organic film has been formed from the vacuum chamber after destroying the vacuum in the vacuum chamber;
wherein
in forming the film on a first one of the multiple target substrates, after the carrying step has been performed, the evacuation step and the preliminary heating step are performed, and then, the film formation step and the removal step are successively performed, and
in forming the film on each of second and subsequent target substrates, the deposition material is maintained in a preliminarily heated state resulting from the preliminary heating step having been performed to form the film on the first target substrate, and the carrying step, the evacuation step, the film formation step, and the removal step are successively performed.
